(19) United States
(12) Patent Application Publication
(10) Pub. No.: US 2026/0088119 A1
(43) Pub. Date: Mar. 26, 2026

(54) SEMICONDUCTOR MEMORY DEVICE, METHOD OF CONTROLLING SEMICONDUCTOR MEMORY DEVICE, AND COMPUTER-READABLE RECORDING MEDIUM

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Toshiaki DOZAKA, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/063,428

(22) Filed: Feb. 26, 2025

(30) Foreign Application Priority Data
Sep. 20, 2024 (JP) 2024-164281

(51) Int. Cl. G11C 29/44

(52) U.S. Cl. CPC G11C 29/44

(57) ABSTRACT

According to one embodiment, a semiconductor memory device includes: a data latch circuit that holds inverted data of readout expected value data of a memory cell to be tested during a memory cell test; and a test-time reference potential setting circuit that shifts a reference potential for determining a logic level of data read out from the memory cell to be tested to a side that makes a normal determination of a potential corresponding to the readout expected value data stricter. The logic level of the data read out from the memory cell to be tested is determined based on the reference potential that has been shifted.

### CROSS-REFERENCE TO RELATED APPLICATIONS

This application is based upon and claims the benefit of priority from Japanese Patent Application No. 2024-164281, filed on Sep. 20, 2024; the entire contents of which are incorporated herein by reference.

### FIELD

Embodiments described herein relate generally to a semiconductor memory device, a method of controlling the semiconductor memory device, and a computer-readable recording medium.

### BACKGROUND

Conventionally, enable/disable determination before/after writing of a fuse element is made by measuring the cell current and checking the fuse resistance value. However, in order to measure the cell current, a waiting time is required for the current to stabilize, which results in a long test time (400 to 500 msec), and thus it takes high test costs.

For this reason, efforts have been made to reduce testing costs by adding a function for making enable/disable determination before/after writing of the fuse element in a function operation. However, in the conventional technology, it has not been possible to perform a reliable determination in a so-called gray area where the determination result may be inverted due to voltage fluctuations or the like.

The present disclosure has been made in consideration of the above, and aims to provide a semiconductor memory device, a method of controlling the semiconductor memory device, and a computer-readable recording medium, which can reliably make a determination even in the so-called gray area even when enable/disable determination is made before/after writing of a fuse element in a function operation.

### BRIEF DESCRIPTION OF THE DRAWINGS

FIG. 1 is a block diagram illustrating an example of a schematic configuration of a semiconductor memory device according to an embodiment;

FIG. 2 is an explanatory diagram illustrating an example of detailed circuits of a one-shot pulse generating unit, a sense amplifier control unit, and a data latch/output unit according to the embodiment;

FIG. 3 is an explanatory diagram of a configuration example of a fuse test control unit according to the embodiment;

FIG. 4 is an explanatory diagram of a configuration example of a reference voltage generating unit according to the embodiment;

FIG. 5 is an explanatory diagram of a specific example of a reference voltage according to the embodiment; and

FIG. 6 is an operation timing chart of the embodiment.

### DETAILED DESCRIPTION

In general, according to one embodiment, a semiconductor memory device includes: a data latch circuit that holds inverted data of readout expected value data of a memory cell to be tested during a memory cell test; and a test-time reference potential setting circuit that shifts a reference potential for determining a logic level of data read out from the memory cell to be tested to a side that makes a normal determination of a potential corresponding to the readout expected value data stricter. The logic level of the data read out from the memory cell to be tested is determined based on the reference potential that has been shifted.

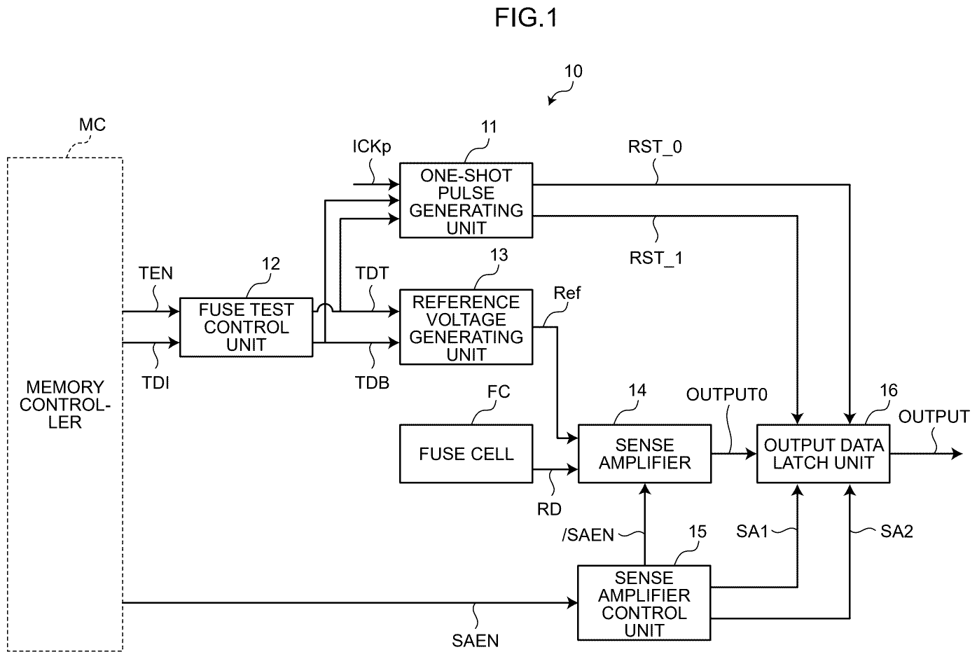

Exemplary embodiments of a semiconductor memory device, and a method of controlling the semiconductor memory device, and a computer-readable recording medium will be explained below in detail with reference to the accompanying drawings. The present invention is not limited to the following embodiments. FIG. 1 is a block diagram of a schematic configuration of a semiconductor memory device according to an embodiment. For ease of understanding, FIG. 1 illustrates a circuit configuration related to one fuse cell FC out of a fuse cell array in which a plurality of fuse cells FC are arranged in an array.

The semiconductor memory device 10 includes a one-shot pulse generating unit 11, a fuse test control unit 12, a reference voltage generating unit 13, a sense amplifier 14, a sense amplifier control unit 15, and a data latch/output unit 16.

The one-shot pulse generating unit 11 outputs a first reset pulse signal RST_0 and a second reset pulse signal RST_1 to the data latch/output unit 16 in synchronization with the internal clock pulse ICKp, based on the timing at which the internal clock pulse ICKp is input.

Here, the first reset pulse signal RST_0 is a signal for setting the held data in the data latch/output unit 16 to the “L” level when the output expected value of the fuse cell FC is at the “H” level. In addition, the second reset pulse signal RST_1 is a signal for setting the held data in the data latch/output unit 16 to the “H” level when the output expected value of the fuse cell FC is at the “L” level.

The fuse test control unit 12 generates first setting data TDT and second setting data TDB for setting a reference voltage Ref based on the test enable signal TEN and the readout expected value data TDI that have been input, and outputs the first setting data TDT and the second setting data TDB to a reference voltage generating unit 13.

The reference voltage generating unit 13 generates a reference voltage Ref based on the first setting data TDT and the second setting data TDB that have been input, and outputs the reference voltage Ref to one input terminal of the sense amplifier 14.

In this case, the reference voltage Ref is set to one of the following. In the case of normal data readout, the reference voltage Ref is set to the reference voltage Ref_N in the normal mode. In addition, when the output expected value during the fuse test is at the “H” level, the reference voltage Ref is set to the reference voltage Ref_H in the “H” verify readout mode. In addition, when the output expected value during the fuse test is at the “L” level, the reference voltage Ref is set to the reference voltage Ref_L in the “L” verify readout mode.

The reference voltage Ref_H in the above-mentioned “H” verify readout mode is set higher than the reference voltage Ref_N in the normal mode. That is, the reference voltage Ref_H in the “H” verify readout mode is set to “Ref_H>Ref_N+α (α>0)”. Therefore, only when a voltage that can be reliably determined as an “H” level is input, the voltage will be determined as an “H” level.

Similarly, the reference voltage Ref_L in the above-mentioned “L” verify readout mode is set lower than the reference voltage Ref_N in the normal mode. That is, the reference voltage Ref_L in the “L” verify readout mode is set to “Ref_L<Ref_N−β (β>0)”. Therefore, only when a voltage that can be reliably determined as the “L” level is input, the voltage will be determined as the “L” level.

The sense amplifier 14 compares the voltage of the signal RD read out from the fuse cell FC with a reference voltage Ref at a timing based on an inverted sense amplifier enable signal /SAEN, and outputs the result to the data latch/output unit 16 as output data OUTPUT0.

The sense amplifier control unit 15 inverts the sense amplifier enable signal that has been input and outputs an inverted sense amplifier enable signal /SAEN to the sense amplifier 14, and outputs a first sense amplifier signal SA1 and a second sense amplifier signal SA2 for controlling the data latch/output unit 16 to the data latch/output unit 16.

The data latch/output unit 16 latches and holds the output data OUTPUT0 based on the first reset pulse signal RST_0 and the second reset pulse signal RST_1 that have been output by the one-shot pulse generating unit 11, and the first sense amplifier signal SA1 and the second sense amplifier signal SA2 that have been output by the sense amplifier control unit 15.

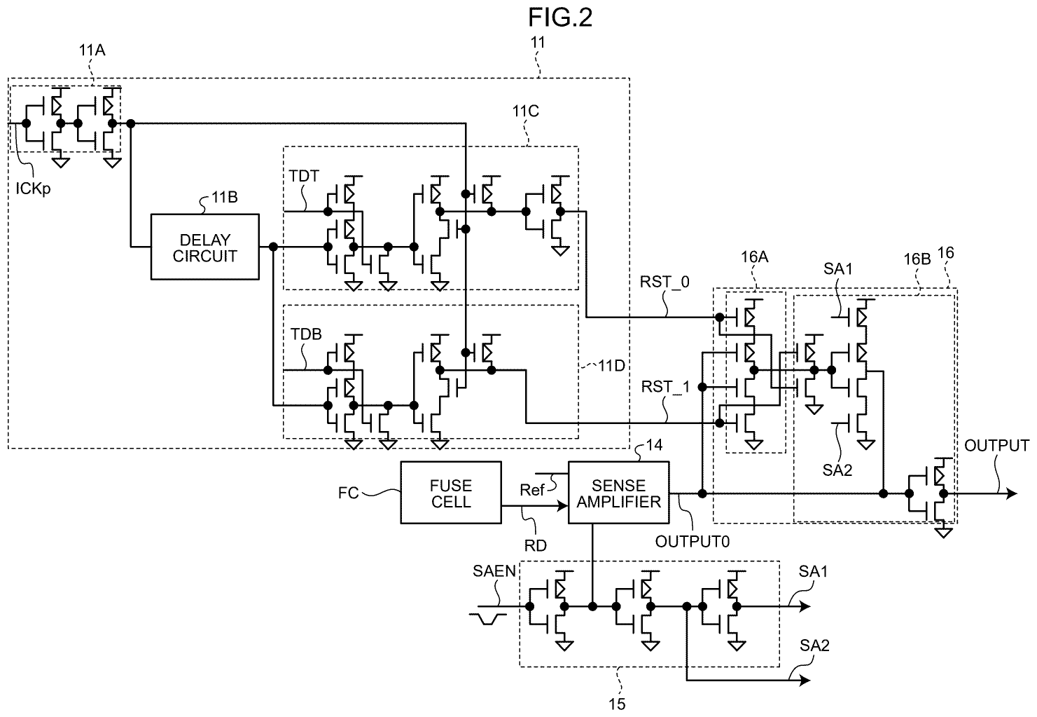

FIG. 2 is an explanatory diagram of a detailed circuit of the one-shot pulse generating unit, the sense amplifier control unit, and the data latch/output unit.

The one-shot pulse generating unit 11 includes: a buffer circuit 11A to which an internal clock pulse ICKp is input; a delay circuit 11B that delays the output of the buffer circuit 11A; a first reset pulse signal generating circuit 11C to one input terminal of which first setting data TDT is input and to the other input terminal of which the output of the delay circuit 11B is input, to generate a first reset pulse signal RST_0; and a second reset pulse signal generating circuit 11D to one input terminal of which second setting data TDB is input and to the other input terminal of which the output of the delay circuit 11B is input, to generate a second reset pulse signal RST_1.

The sense amplifier control unit 15 is input with the sense amplifier enable signal SAEN, and outputs an inverted sense amplifier enable signal /SAEN, which is an inverted signal of the sense amplifier enable signal SAEN, to the enable terminal of the sense amplifier 14. In addition, the sense amplifier control unit 15 outputs the sense amplifier enable signal SAEN to the data latch/output unit 16 as a first sense amplifier signal SA1. In addition, the sense amplifier control unit 15 outputs the inverted sense amplifier enable signal /SAEN to the data latch/output unit 16 as a second sense amplifier signal SA2.

The data latch/output unit 16 latches and holds the output data of the sense amplifier 14 in the normal readout mode. In addition, the data latch/output unit 16 outputs the first reset pulse signal RST_0 or the second reset pulse signal RST_1 output from the one-shot pulse generating unit 11 to the data latch/output unit 16 in the “H” verify mode and in the “L” verify mode.

When a one-shot pulse is input as the first reset pulse signal RST_0, the data latch/output unit 16 holds “L” data as inverted data of the expected value data in the “H” verify readout mode. In addition, when a one-shot pulse is input as the second reset pulse signal RST_1, the data latch/output unit 16 holds “H” data as inverted data of the expected value data in the “L” verify readout mode.

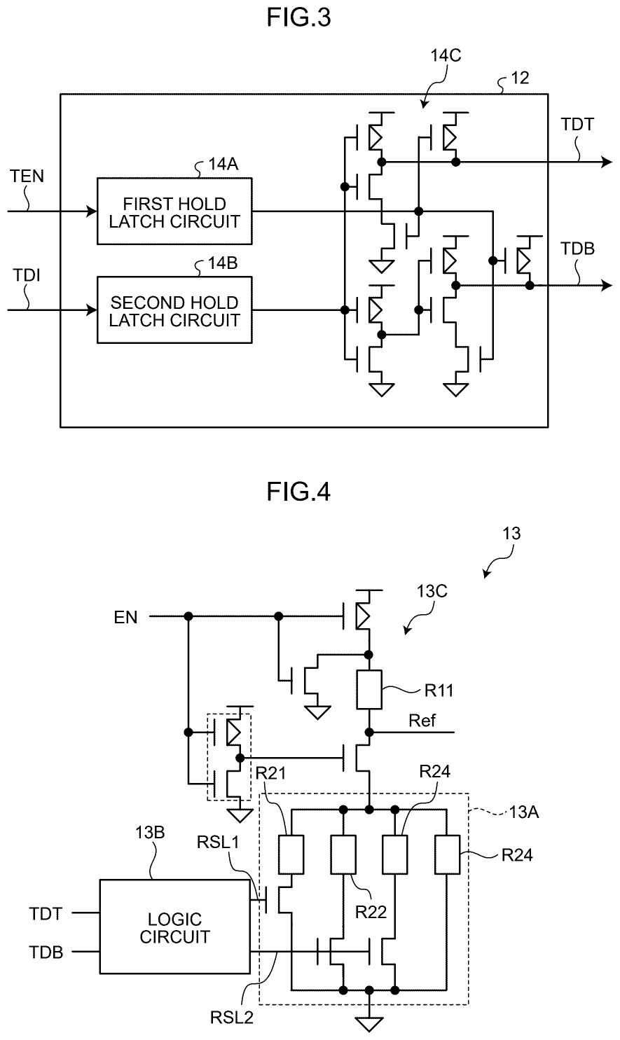

Next, the fuse test control unit 12 will be described in detail. FIG. 3 is an explanatory diagram of a configuration example of the fuse test control unit. The fuse test control unit 12 includes a first hold latch circuit 14A, a second hold latch circuit 14B, and a setting data generating unit 14C.

The first hold latch circuit 14A is input with the test enable signal TEN from the memory controller MC and holds the test enable signal TEN. The second hold latch circuit 14B is input with the readout expected value data TDI from the memory controller MC and holds the readout expected value data TDI.

When the test enable signal TEN is at “L” level, that is, in the non-test mode, the setting data generating unit 14C sets the first setting data TDT and the second setting data TDB to both “H” level or both to “L” level.

In addition, when the test enable signal TEN is at the “H” level, that is, in the test mode, the setting data generating unit 14C sets one of the first setting data TDT and the second setting data TDB to the “H” level and the other to the “L” level based on the readout expected value data TDI.

Next, the reference voltage generating unit 13 will be described in detail. In the following description, it is assumed that the readout enable signal EN is an “L” active signal. That is, it is assumed that when the readout enable signal EN is at the “L” level, data can be read out from the fuse cells FC.

FIG. 4 is an explanatory diagram of a configuration example of the reference voltage generating unit. The reference voltage generating unit 13 roughly includes a first voltage dividing resistor R11, a voltage dividing resistor selection circuit 13A including a plurality of second voltage dividing resistors R21 to R24, a logic circuit 13B, and a first voltage dividing resistor connection circuit 13C.

In the case of the readout enable signal EN=“H” level, the first voltage dividing resistor connection circuit 13C electrically disconnects the first voltage dividing resistor R11 from the high potential side power supply and the voltage dividing resistor selection circuit 13A. In addition, in the case of the readout enable signal EN=“L” level, the first voltage dividing resistor connection circuit 13C connects the first voltage dividing resistor R11 to the high potential side power supply and the voltage dividing resistor selection circuit 13A.

The logic circuit 13B outputs a first voltage dividing resistor selection signal RSL1 and a second voltage dividing resistor selection signal RSL2 for selecting the second voltage dividing resistors R21 to R24 to be connected to the first voltage dividing resistor in the voltage dividing resistor selection circuit 13A based on the first setting data TDT and the second setting data TDB.

Then, based on the first setting data TDT and the second setting data TDB, when the readout expected value data TDI is at the “L” level, the logic circuit 13B outputs a first voltage dividing resistor selection signal RSL1 and a second voltage dividing resistor selection signal RSL2 such that the combined resistance value of the second voltage dividing resistors selected in the voltage dividing resistor selection circuit 13A is lower than the resistance value of the second voltage dividing resistor when the operating mode is the normal readout mode.

More specifically, for example, if the resistance values of the second voltage dividing resistors R21 to R24 are all equal, in the normal readout mode, by setting the second voltage dividing resistor selection signal RSL1=“H” level and the second voltage dividing resistor selection signal RSL2=“L” level, the second voltage dividing resistor R21 and the second voltage dividing resistor R24 are connected to the first voltage dividing resistor R11.

In this case, the combined resistance value of the second voltage dividing resistors only needs to be reduced by increasing the number of second voltage dividing resistors connected in parallel compared to that in the normal readout mode, for example, so that all of the second voltage dividing resistors R21 to R24 are connected to the first voltage dividing resistor R11 by setting the first voltage dividing resistor selection signal RSL1=“H” level and the second voltage dividing resistor selection signal RSL2=“H” level, or that the second voltage dividing resistors R22 to R24 are connected to the first voltage dividing resistor R11 by setting the first voltage dividing resistor selection signal RSL1=“L” level and the second voltage dividing resistor selection signal RSL2=“H” level.

In addition, based on the first setting data TDT and the second setting data TDB, when the readout expected value data TDI is at the “H” level, the logic circuit 13B outputs voltage dividing resistor selection signals RSL1 and RSL2 such that the combined resistance value of the second voltage dividing resistors selected in the voltage dividing resistor selection circuit 13A is higher than the resistance value of the second voltage dividing resistor when the operating mode is the normal readout mode.

In this case, the combined resistance value of the second voltage dividing resistors only needs to be higher by reducing the number of second voltage dividing resistors connected in parallel compared to that in the normal readout mode, for example, so that only the second voltage dividing resistor R24 is connected to the first voltage dividing resistor R11 by setting the first voltage dividing resistor selection signal RSL1 to “L” level and the second voltage dividing resistor selection signal RSL2 to “L” level.

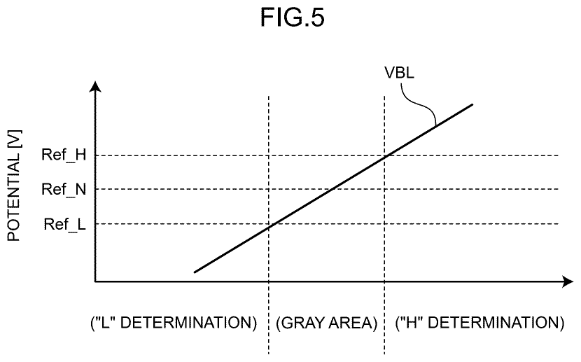

FIG. 5 is a diagram illustrating a specific example of the reference voltage. In FIG. 5, a potential VBL is the potential of the signal RD read out from the fuse cell FC. As illustrated in FIG. 5, when the reference voltage Ref in the normal readout mode is denoted by Ref_N, when the readout expected value data TDI is at the “H” level, the reference voltage Ref is set to Ref_H>Ref_N.

As a result, the potential VBL of the signal RD read out from the fuse cell FC is not determined as the “H” level unless the potential VBL is higher than that in the normal readout mode. Therefore, the data read out from the fuse cell FC has a higher potential level, and can be determined to be reliably at the “H” level.

On the other hand, when the readout expected value data TDI is at the “L” level, the reference voltage Ref is set to Ref_L<Ref_N. As a result, the potential VBL of the signal RD read out from the fuse cell FC is not determined as the “L” level unless the potential VBL is lower than that in the normal readout mode. Therefore, the data read out from the fuse cell FC has a lower potential level and can be determined to be reliably at the “L” level.

As a result, even if there is a fluctuation in the potential level due to noise or the like, the “H” level and “L” level can be determined more reliably, and the readout data can be determined reliably even in the so-called gray area where the determination result may be inverted due to fluctuations in the potential level.

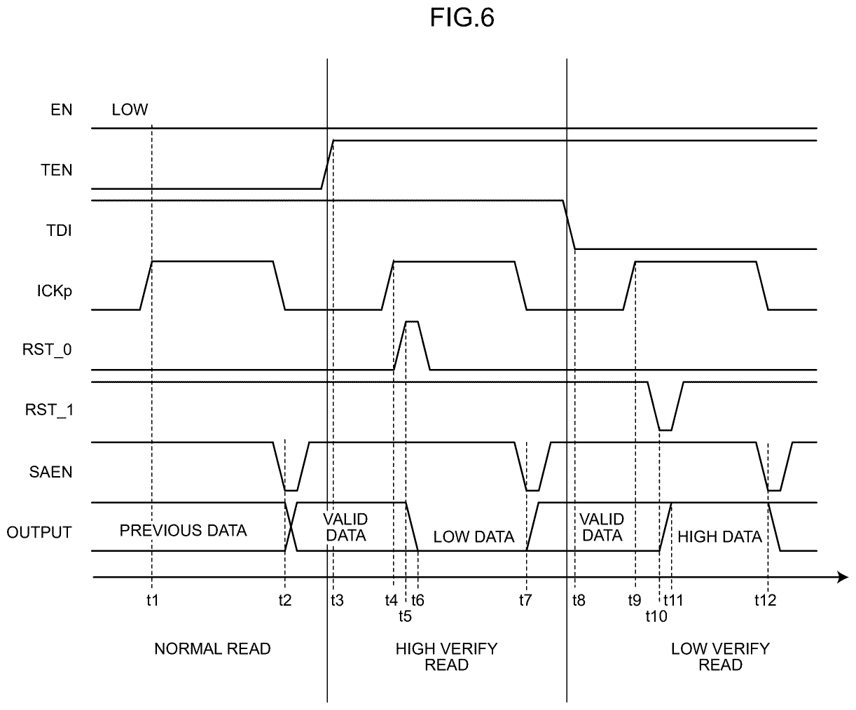

Next, an operation example of the embodiment will be described. FIG. 6 is an operation timing chart of the embodiment. In the present embodiment, as mentioned above, there are three modes: the normal readout mode, the “H” verify readout mode, and the “L” verify readout mode.

First, the operation in the normal readout mode will be described. In the normal readout mode, the test enable signal TEN is at the “L” level. Therefore, even if the internal clock pulse ICKp transitions to the “H” level at time t1, the first reset pulse signal RST_0 remains at the “L” level.

After that, at time t2, when the sense amplifier enable signal SAEN transitions to “L”, the data of the fuse cell FC is read out by the sense amplifier 14, and the data (“H” level or “L” level) stored in the fuse cell FC is output as output data OUTPUT.

Next, the operation in the “H” verify readout mode will be described. First, as in a case illustrated at time t3, if the test enable signal TEN transitions to “H”, the readout mode becomes the “H” verify readout mode or the “L” verify readout mode. In this case, at time t3, the readout expected value data TDI is at “H”, so that the data in the fuse cell FC after writing should be at the “H” level, and the mode shifts to the “H” verify readout mode.

For this reason, the logic circuit 13B of the reference voltage generating unit 13 outputs a first voltage dividing resistor selection signal RSL1 and a second voltage dividing resistor selection signal RSL2 for selecting the second voltage dividing resistors R21 to R24 to be connected to the first voltage dividing resistor in the voltage dividing resistor selection circuit 13A based on the first setting data TDT and the second setting data TDB.

More specifically, since the readout expected value data TDI is at the “H” level, the logic circuit 13B outputs the voltage dividing resistor selection signals RSL1 and RSL2 such that the combined resistance value of the second voltage dividing resistors selected in the voltage dividing resistor selection circuit 13A is higher than the resistance value of the second voltage dividing resistor when the operating mode is the normal readout mode.

In this case, the combined resistance value of the second voltage dividing resistors is increased by reducing the number of second voltage dividing resistors connected in parallel, for example, so that only the second voltage dividing resistor R24 is connected to the first voltage dividing resistor R11 by setting the first voltage dividing resistor selection signal RSL1 to “L” level and the second voltage dividing resistor selection signal RSL2 to “L” level.

As a result, the reference voltage Ref is set to Ref_H>Ref_N, so that it can be determined that the potential of the data read out from the fuse cell FC is reliably at the “H” level. Therefore, even if there is a fluctuation in the potential level due to noise or the like, it can be more reliably determined to be at the “H” level, and the readout data can be reliably determined even in the so-called gray area where the determination result may be inverted due to fluctuations in the potential level.

Then, if the internal clock pulse ICKp transitions to the “H” level at time t4, the first reset pulse signal RST_0 transitions to the “H” level at time t5. As a result, at time t6, since the readout expected value data TDI is at “H” level, the data latch/output unit 16 latches “L” level data, which is an inverted signal of the readout expected value data TDI. Accordingly, the output data OUTPUT becomes the “L” level.

After that, at time t7, when the sense amplifier enable signal SAEN transitions to “L”, the data of the fuse cell FC is read out by the sense amplifier 14, and the data (“H” level or “L” level) stored in the fuse cell FC is output as output data OUTPUT.

Next, the operation in the “L” verify readout mode will be described. First, as in a case illustrated at time t8, the test enable signal TEN remains at “H”, and at time t8, the readout expected value data TDI is at “L”, so that the data of the fuse cell FC after writing should be at the “L” level, and the mode transitions to the “L” verify readout mode.

For this reason, the logic circuit 13B of the reference voltage generating unit 13 outputs a first voltage dividing resistor selection signal RSL1 and a second voltage dividing resistor selection signal RSL2 for selecting the second voltage dividing resistors R21 to R24 to be connected to the first voltage dividing resistor in the voltage dividing resistor selection circuit 13A based on the first setting data TDT and the second setting data TDB.

More specifically, since the readout expected value data TDI is at the “L” level, the logic circuit 13B outputs voltage dividing resistor selection signals RSL1 and RSL2 such that the combined resistance value of the second voltage dividing resistors selected in the voltage dividing resistor selection circuit 13A is lower than the resistance value of the second voltage dividing resistor when the operating mode is the normal readout mode.

More specifically, the combined resistance value of the second voltage dividing resistors only needs to be reduced by increasing the number of second voltage dividing resistors connected in parallel compared to that in the normal readout mode, for example, so that all of the second voltage dividing resistors R21 to R24 are connected to the first voltage dividing resistor R11 by setting the first voltage dividing resistor selection signal RSL1=“H” level and the second voltage dividing resistor selection signal RSL2=“H” level, or that the second voltage dividing resistors R22 to R24 are connected to the first voltage dividing resistor R11 by setting the first voltage dividing resistor selection signal RSL1=“L” level and the second voltage dividing resistor selection signal RSL2=“H” level.

As a result, the reference voltage Ref is set to Ref_L<Ref_N, so that it can be determined that the potential of the data read out from the fuse cell FC is reliably at the “L” level. Therefore, even if there is a fluctuation in the potential level due to noise or the like, it can be more reliably determined to be at the “H” level, and the readout data can be reliably determined even in the so-called gray area where the determination result may be inverted due to fluctuations in the potential level.

Then, if the internal clock pulse ICKp transitions to the “H” level at time t9, the second reset pulse signal RST_1 transitions to the “L” level at time t10. As a result, at time t11, since the readout expected value data TDI is at “L” level, the data latch/output unit 16 latches “H” level data, which is an inverted signal of the readout expected value data TDI.

Accordingly, the output data OUTPUT becomes “H” level. After that, at time t12, when the sense amplifier enable signal SAEN transitions to “L”, the data of the fuse cell FC is read out by the sense amplifier 14, and the data (“H” level or “L” level) stored in the fuse cell FC is output as output data OUTPUT.

That is, according to the embodiment, the logic level of the held data in the output data latch circuit and the logic level of the memory cell to be tested are sequentially output via the output line through which the output data OUTPUT is output based on the operation mode.

As described above, according to the embodiment, even when enable/disable determination is made before/after writing of a fuse element in a function operation, the determination can be made reliably even in a so-called gray area. Furthermore, even if the previous value is not held, that is, data is not written, correctly due to an insufficient operating margin of the readout circuit, it can be determined based on the data (the inverted data of the readout expected value) in the output data latch unit.

Although the semiconductor memory device of the above embodiment has been described mainly with an example composed by circuits, the present disclosure is not limited thereto. For example, a program for executing the above-mentioned operations of the semiconductor memory device, that is, a computer program for causing the computer to execute: a step of holding inverted data of readout expected value data of a memory cell to be tested during a memory cell test; a step of shifting a reference potential for determining a logic level of data read out from the memory cell to be tested to a side that makes a normal determination of a potential corresponding to the readout expected value data stricter; and a step of determining the logic level of data read out from the memory cell to be tested based on the reference potential that has been shifted, and a computer program for causing the computer to execute a step of generating and outputting the inverted data based on a test enable signal for transitioning to the memory cell test and the readout expected value data, are stored in a computer-readable recording medium such as a ROM of the semiconductor memory device. The semiconductor memory device may be configured so as to realize the above operations by a CPU of the semiconductor memory device reading out the computer program from the recording medium and executes the computer program.

It should be noted that in this case, the computer program executed by the semiconductor manufacturing device of the embodiment may be configured to be provided by being pre-installed in a ROM or the like, or may be configured to be recorded and provided in an installable or executable format file on a computer-readable recording medium such as a CD-ROM, a flexible disk (FD), a CD-R, or a digital versatile disk (DVD). Furthermore, the computer program executed by the semiconductor manufacturing device of the embodiment may be configured to be stored on a computer connected to a network such as the Internet and provided by being downloaded via the network. In addition, the computer program executed by the semiconductor manufacturing device of the embodiment may be configured to be provided or distributed via a network such as the Internet.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a data latch circuit that holds inverted data of readout expected value data of a memory cell to be tested during a memory cell test; and
a test-time reference potential setting circuit that shifts a reference potential for determining a logic level of data read out from the memory cell to be tested to a side that makes a normal determination of a potential corresponding to the readout expected value data stricter, wherein
the logic level of the data read out from the memory cell to be tested is determined based on the reference potential that has been shifted.

2. The semiconductor memory device according to claim 1, further comprising:
a latch data generation circuit that generates the inverted data based on a test enable signal for transitioning to the memory cell test and the readout expected value data, and outputs the generated inverted data to the data latch circuit.

3. The semiconductor memory device according to claim 2, wherein
the latch data generation circuit includes a one-shot pulse generation circuit that generates inverted data of the readout expected value data by a one-shot pulse corresponding to the readout expected value data.

4. The semiconductor memory device according to claim 3, wherein
the one-shot pulse generation circuit generates a first reset pulse for resetting held data in the data latch circuit to an “L” level when the readout expected value data is at an “H” level, and generates a second reset pulse for resetting the held data in the data latch circuit to an “H” level when the readout expected value data is at an “L” level.

5. The semiconductor memory device according to claim 1, further comprising:
a sense amplifier that determines a logic level of memory data of the memory cell to be tested based on the reference potential and outputs the determined logic level as output data.

6. The semiconductor memory device according to claim 5, wherein
a logic level of held data in the data latch circuit and a logic level of the memory cell to be tested are sequentially output via an output line based on an operation mode.

7. A method of controlling a semiconductor memory device, the method comprising:
holding inverted data of readout expected value data of a memory cell to be tested during a memory cell test;
shifting a reference potential for determining a logic level of data read out from the memory cell to be tested to a side that makes a normal determination of a potential corresponding to the readout expected value data stricter; and
determining the logic level of data read out from the memory cell to be tested based on the reference potential that has been shifted.

8. The method of controlling the semiconductor memory device according to claim 7, the method further comprising:
generating the inverted data based on a test enable signal for transitioning to the memory cell test and the readout expected value data, and outputting the generated inverted data.

9. A computer-readable recording medium having a computer program recorded thereon for controlling a semiconductor memory device by a computer, the semiconductor memory device storing readout expected value data and including a mechanism that determines whether stored data is normal based on the readout expected value data, the computer program causing the computer to execute:
holding inverted data of the readout expected value data of a memory cell to be tested during a memory cell test;
shifting a reference potential for determining a logic level of data read out from the memory cell to be tested to a side that makes a normal determination of a potential corresponding to the readout expected value data stricter; and
determining the logic level of data read out from the memory cell to be tested based on the reference potential that has been shifted.

10. The computer-readable recording medium according to claim 9, wherein
the computer program causes the computer to further execute generating the inverted data based on a test enable signal input to the semiconductor memory device for transitioning to the memory cell test and the readout expected value data, and outputting the generated inverted data.
